(19) United States
(12) Patent Application Publication
(10) Pub. No.: US 2008/0157178 A1
(43) Pub. Date: Jul. 3, 2008

(54) Flash memory device and method for manufacturing thereof

(76) Inventor: Dong Oog Kim, Yongin-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/936,849

(22) Filed: Nov. 8, 2007

(30) Foreign Application Priority Data
Dec. 27, 2006 (KR) 10-2006-0134644

(51) Int. Cl. H01L 21/336; H01L 29/788

(52) U.S. Cl. 257/321; 438/261; 257/E29.3; 257/E21.422

(57) ABSTRACT

A flash memory device and fabricating method thereof are provided. A device isolating layer, a tunnel oxide film, and a floating gate can be formed on a substrate. An oxide-nitride-oxide (ONO) layer can be formed over the substrate, and a control gate can be formed on the ONO layer. A spacer can be formed of a high-temperature oxide film and a nitride film at sidewalls of the control gate.

### CROSS-REFERENCE TO RELATED APPLICATION

The present application claims the benefit under 35 U.S.C. §119 of Korean Patent Application No. 10-2006-0134644, filed Dec. 27, 2006, which is hereby incorporated by reference in its entirety.

### BACKGROUND

Flash memory is a nonvolatile memory medium that allows data to be stored and not damaged even when no power is supplied. Flash memory can perform data processing, such as recording, reading, and deleting, with relatively high speed. Accordingly, flash memory is often used for the Bios of a personal computer and for storing data in set-top boxes, printers, and network servers. Flash memory has also been used recently in digital cameras and cellular phones.

The characteristics of cycling and data retention are very important for flash memory. Cycling which can often be the most important characteristic, refers to the fact that although reading, writing, and erasing of data can be repeated several times, operations that move electrons in and out of a floating gate can be repeated without changing the characteristics of the flash memory. Data retention characteristics can be degraded if electrons in a floating gate escape through an ONO layer and a tunnel oxide film. In particular, data retention characteristics can be especially degraded if a leakage current flowing through an outer portion of a cell region is present and if electrons escape through a floating gate side.

A problem that related art flash memory experiences is that charges around a floating gate may not dissipate even after a subsequent process has occurred. This problem is appearing regularly as flash memory is scaled to 0.13 μm technologies and below.

Thus, there exists a need in the art for an improved flash memory and fabricating method thereof.

### BRIEF SUMMARY

Embodiments of the present invention provide a flash memory device and manufacturing thereof. Electrons stored in a floating gate of a flash memory device can be inhibited from escaping to outer portions of the device. Additionally, electrons in a spacer nitride film can be inhibited from entering into a floating gate.

In an embodiment, a method for manufacturing a flash memory device can include forming a device isolating layer, a tunnel oxide film, and a floating gate on a substrate. An oxide-nitride-oxide (ONO) layer can be formed over the substrate, and a control gate can be formed on the ONO layer. A high-temperature oxide film can be formed over the substrate and the control gate, and a nitride film can be formed on the high-temperature oxide Film. A spacer can be formed by etching the high-temperature oxide film and the nitride film.

A flash memory device according to an embodiment of the present invention can include: a substrate provided with a device isolating layer; a tunnel oxide film and a floating gate on the substrate; an ONO layer on the floating gate; a control gate on the ONO layer; and a spacer formed on the sides of the tunnel oxide film, the floating gate, the ONO layer, and the control gate, wherein the spacer comprises a high-temperature oxide film and a nitride film.

### BRIEF DESCRIPTION OF THE DRAWINGS

FIGS. 1 to 8 are cross-sectional views showing a process for manufacturing a flash memory device according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

Referring to FIG. 1, a substrate 20 can be prepared and partitioned into a cell region and peripheral region. In one embodiment, in forming device isolation layers 26, an oxide film 21, a nitride film 22, and an insulating layer 23 can be sequentially formed on the substrate 20. The insulating layer 23 can be any suitable material known in the art, for example, tetraethyl orthosilicate (TEOS).

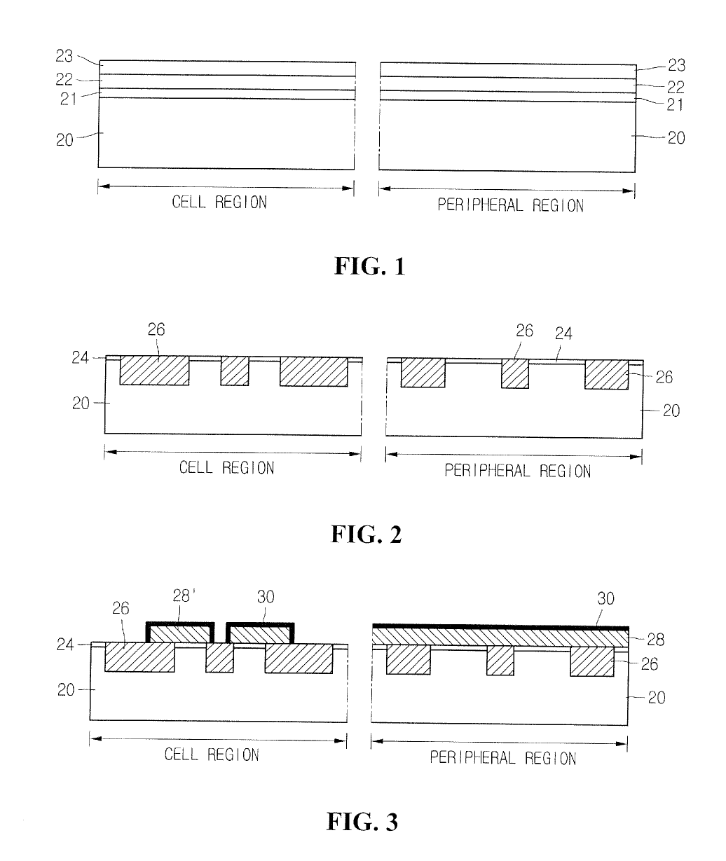

Referring to FIG. 2, a mask material (not shown) can be deposited on the insulating layer 23 and can then be patterned. The substrate 20 can be etched by performing an etching process using the mask material as an etching mask. The mask material can then be removed.

Insulating material can be gap-filled on the substrate 20, and a trench chemical mechanical polishing (CMP) process can be performed to form a device isolating layer 26 on the substrate 20. The device isolating layer 26 can be used as a region for insulating various devices that may be formed later on the substrate 20. The insulating material can be any suitable material known in the art, for example, high-density plasma undoped silicate glass (HDP-USG).

The nitride film can be removed. Accordingly, an oxide film 24 can be formed on the substrate between regions of the device isolating layer 26.

Although not shown in FIG. 2, an ion implantation process can be selectively performed on the substrate 20 including the device isolating layer 26 so that a P well and an N well can be formed on the substrate 20.

Referring to FIG. 3, a polysilicon layer can be deposited over the substrate 20, and then the substrate 20 of the cell region can be patterned to form a first polysilicon layer 28′. The first polysilicon layer 28′ can be part of a floating gate, and below the floating gate can be a tunnel oxide film formed by patterning the oxide film 24. In an embodiment, the first polysilicon layer 28′ can be doped with dopants. The first polysilicon layer 28′, isolated between the oxide film 24 and an oxide-nitride-oxide (ONO) layer 30 to help retain charges (electrons), can have an improved excited state.

A first oxide layer (not shown), a nitride layer (not shown), and a second oxide layer (not shown) can be sequentially deposited over the substrate 20. An annealing process can be performed, and the substrate 20 of the cell region can be patterned to form the ONO layer 30. The ONO layer 30 can be on and at the sides of the first polysilicon layer 28′. The ONO layer 30 can be used to help insulate upper portions of the cell region from lower portions of the cell region.

Then, a mask material (not shown) can be formed over the substrate 20 and can be patterned such that the mask material of the peripheral region is removed, forming a mask layer (not shown) only on the substrate 20 of the cell region and exposing the ONO layer 30 on the peripheral region.

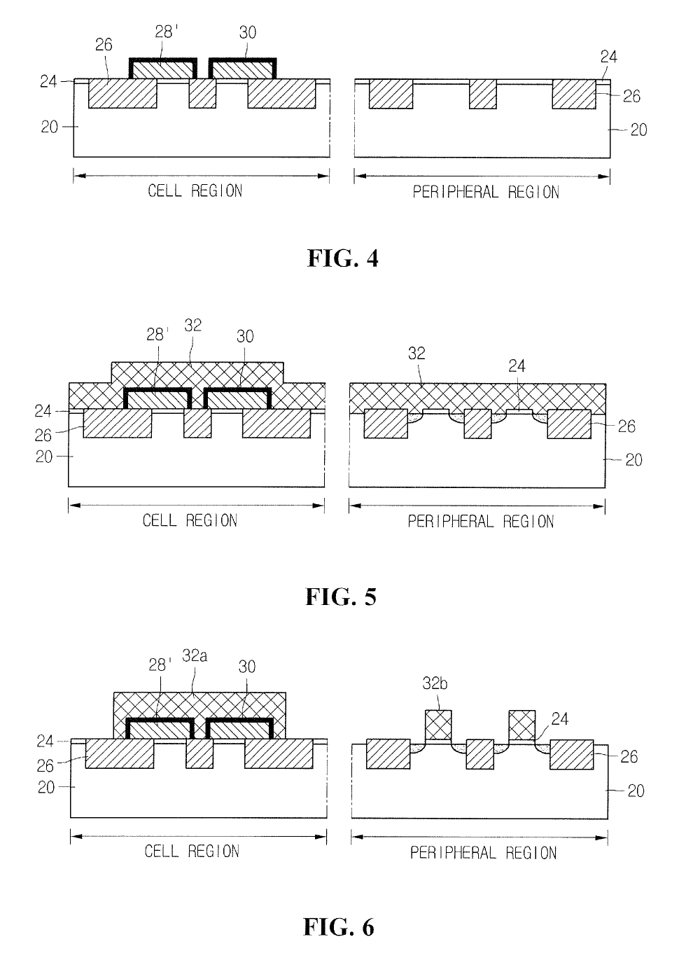

Referring to FIG. 4, the polysilicon layer 28 and the ONO layer 30 on the substrate 20 of the peripheral region can be removed by etching the substrate 20 using the mask layer as an etch mask.

Referring to FIG. 5, a polysilicon layer 32 can be deposited over the substrate 20 including the cell region and the peripheral region.

In an embodiment, portions of the oxide film 24 on the substrate 20 of the peripheral region can be selectively removed prior to depositing the polysilicon layer 32. An impurity region can be formed on a portion of the substrate 20 where the oxide film 24 has been removed.

Referring to FIG. 6, the polysilicon layer 32 can be patterned to form second polysilicon layers 32a and 32b.

The second polysilicon layer 32a of the substrate 20 of the cell region can be formed covering the ONO layer 30. In an embodiment, the second polysilicon layer 32a can be formed over more than one floating gate. For example, the second polysilicon layer 32 can be formed over two floating gates formed of the oxide film 24 and the first polysilicon layer 28′. The second polysilicon layer 32b of the substrate 20 of the peripheral region can be formed in a region between device isolating layers 26 that can be referred to as a gate forming region. The second polysilicon layer 32a formed on the substrate 20 of the cell region can be part of a control gate, and the second polysilicon layer 32b formed on the substrate of the peripheral region can be part of a floating gate.

In an embodiment, the second polysilicon layer 32a formed on the substrate 20 of the cell region can be used to apply a bias voltage that excites electrons in the first polysilicon layer 28′ to charge or discharge them.

Referring to FIG. 7, a high-temperature oxide film 41 can be formed over the substrate 20 and a nitride film 42 can be formed on the high-temperature oxide film 41. The high-temperature oxide film 41 can be, for example, an oxide film deposited at a temperature of about 500° C. to about 800° C. In an embodiment, the high-temperature oxide film 41 can be an oxide film deposited at a temperature of about 780° C. Also, the high-temperature oxide film 41 can be formed to a thickness of, for example, about 100 Å to about 200 Å. The high-temperature oxide film can be deposited using any suitable deposition method known in the art, for example, a low pressure chemical vapor deposition (LP-CVD) method.

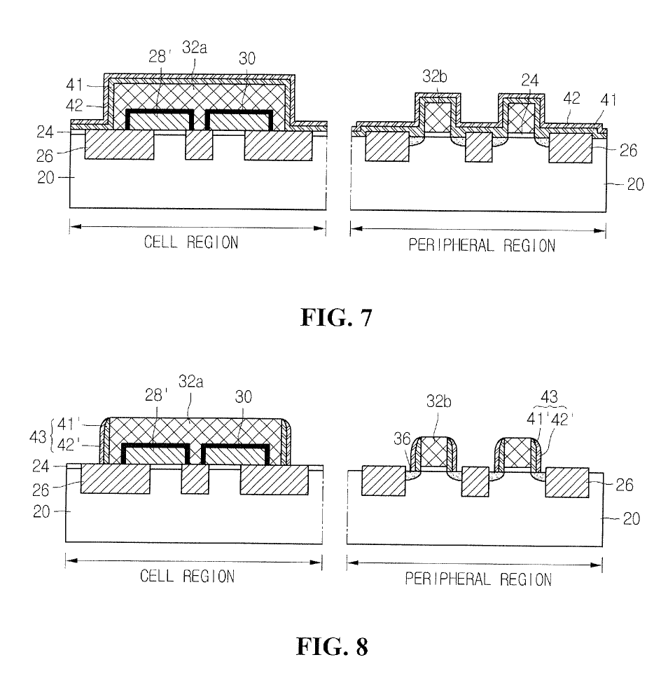

Referring to FIG. 8, the high-temperature oxide film 41 and the nitride film 42 can be blanket etched to form a spacer 43 formed of a high-temperature oxide film pattern 41′ and a nitride pattern 42′ on the sidewalls of the second polysilicon layers 32a and 32b. The high-temperature oxide film 41 and the nitride film 42 can be etched through any suitable process known in the art, for example, a reactive ion etching (RIE) process. Then, an ion implantation process can be performed using the second polysilicon layers 32a and 32b and the spacer 43 as a mask to form an impurity region 36 inside the substrate 20. The impurity region 36 can be a source and drain region.

In an embodiment of the present invention, a device isolating layer, a tunnel oxide film, and a floating gate can be formed on the substrate of the memory flash device.

An ONO layer can be formed on the floating gate, and a control gate can be formed on the ONO layer.

A spacer can be formed on the sides of the memory device stack including the tunnel oxide film the floating gate, the ONO layer, and the control gate. The spacer can be formed of a high-temperature oxide film and a nitride film. The high-temperature oxide film can be an oxide film deposited at a temperature of about 500° C. to about 800° C., for example, about 780° C. Additionally, the high-temperature oxide film can be formed to a thickness of about 100 Å to about 200 Å.

According to embodiments of the present invention, a high-temperature oxide film, which can be more structurally rigid than a TEOS layer, can be formed as part of a spacer to help inhibit electrons stored in a floating gate of the flash memory device from escaping to the outer portions of the device. The high-temperature oxide film can also help inhibit electrons in the spacer nitride film from entering into the floating gate. Thus, the electrical characteristics of the flash memory device can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with ally embodiment, it is submitted that it is within the purview of one skilled in the art to effect such feature, structure, or characteristic in connection with other ones of the embodiments.

Although embodiments have been described with reference to a number of illustrative embodiments thereof it should be understood that numerous other modifications and embodiments can be devised by those skilled in the art that will fall within the spirit and scope of the principles of this disclosure. More particularly, various variations and modifications are plausible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a flash memory device, comprising:
forming a device isolating layer on a substrate;
forming a tunnel oxide film and a floating gate on the substrate;
forming an oxide-nitride-oxide (ONO) layer on the substrate;
forming a control gate on the ONO layer;
forming a high-temperature oxide film on the substrate and the control gate;
forming a nitride film on the high-temperature oxide film; and
forming a spacer by etching the high-temperature oxide film and the nitride film.

2. The method according to claim 1, wherein the high-temperature oxide film comprises an oxide film formed at a temperature of about 500° C. to about 800° C.

3. The method according to claim 1, wherein the high-temperature oxide film comprises an oxide film formed at a temperature of about 780° C.

4. The method according to claim 17 wherein the high-temperature oxide film has a thickness of about 100 Å to about 200 Å.

5. The method according to claim 1, wherein forming the high-temperature oxide film comprises using a low pressure chemical vapor deposition (LP-CVD) method.

6. A flash memory device, comprising:
a substrate provided with a device isolating layer;
a tunnel oxide film and a floating gate on the substrate;
an ONO layer on the floating gate;
a control gate on the ONO layer; and
a spacer on sidewalls of the control gate, wherein the spacer comprises a high-temperature oxide film and a nitride film.

7. The flash memory device according to claim 6, wherein the high-temperature oxide film comprises oxide film formed at a temperature of about 500° C. to about 800° C.

8. The flash memory device according to claim 6, wherein the high-temperature oxide film has a thickness of about 100 Å to about 200 Å.
